(19) United States
(12) Patent Application Publication
(10) Pub. No.: US 2023/0282550 A1
(43) Pub. Date: Sep. 7, 2023

(54) SEMICONDUCTOR DEVICE

(71) Applicant: FUJI ELECTRIC CO., LTD., Kawasaki-shi (JP)

(72) Inventors: Ginji UCHIBE, Tokyo (JP); Yuji SUZUKI, Tokyo (JP)

(73) Assignee: FUJI ELECTRIC CO., LTD., Kawasaki-shi (JP)

(21) Appl. No.: 18/161,239

(22) Filed: Jan. 30, 2023

(30) Foreign Application Priority Data
Mar. 4, 2022 (JP) 2022-033673

(51) Int. Cl. H01L 23/473; H01L 25/16

(52) U.S. Cl. CPC H01L 23/473; H01L 25/16

(57) ABSTRACT

A semiconductor device includes an elongated cooler through which a refrigerant flows; a plurality of semiconductor modules, each including one or more semiconductor elements; and a passive element configured to drive the plurality of semiconductor modules, the cooler includes a first cooling surface; and a second cooling surface opposing the first cooling surface, the plurality of semiconductor modules is arrayed in a longitudinal direction of the cooler and is coupled to, or is in contact with, the first cooling surface, and the passive element is coupled to, or is in contact with, the second cooling surface.

### CROSS REFERENCE TO RELATED APPLICATION

This application is based on, and claims priority from, Japanese Patent Application No. 2022-33673, filed Mar. 4, 2022, the entire contents of which are incorporated herein by reference.

### BACKGROUND

### Technical Field

This disclosure relates to a semiconductor device.

### Related Art

A semiconductor device generally includes a passive element such as a capacitor, a reactor, etc. The service life of a semiconductor device depends on, in particular, the service life of a passive element. The service life of a passive element is affected by heat generated by the passive element.

Regarding cooling of a passive element, Japanese Patent Application Laid-Open Publication No. 2019-140911 discloses a stacked structure in which cooling pipes included in a cooler are stacked together with electronic components that constitute a power conversion circuit. In the stacked structure, a plurality of semiconductor modules and a capacitor that is a passive element are provided in a plurality of gaps between the cooling pipes. More specifically, in the stacked structure, the plurality of semiconductor modules and the capacitor are stacked in a spaced-apart manner in a stacking direction of the plurality of cooling pipes.

In the stacked structure disclosed in Japanese Patent Application Laid-Open Publication No. 2019-140911, as the number of semiconductor modules increases, the number of stacks of each of the semiconductor modules and each of the cooling pipes increases. As a result, the greater the number of semiconductor modules, the greater the size of the stacked structure in the stacking direction.

### SUMMARY OF THE INVENTION

An object of one aspect according to the present disclosure is to provide a semiconductor device capable of increasing the cooling efficiency of a passive element without increasing the size of the semiconductor device in the stacking direction, as compared to in the prior art.

A semiconductor device according to an aspect of the present disclosure includes an elongated cooler through which a refrigerant flows; a plurality of semiconductor modules, each including one or more semiconductor elements; and a passive element configured to drive the plurality of semiconductor modules, the cooler includes a first cooling surface; and a second cooling surface opposing the first cooling surface, the plurality of semiconductor modules is arrayed in a longitudinal direction of the cooler and is coupled to, or is in contact with, the first cooling surface, and the passive element is coupled to, or is in contact with, the second cooling surface.

### BRIEF DESCRIPTION OF THE DRAWINGS

FIG. 1 is a perspective view schematically showing a main part of a power converter 10 according to a first embodiment.

FIG. 2 is a diagram showing a configuration of the power converter according to the first embodiment.

FIG. 3 is a diagram showing an internal structure of a cooler 100 included in the power converter 10 according to the first embodiment.

FIG. 4 is a diagram showing a flow path for a refrigerant in the cooler 100 included in the power converter 10 according to the first embodiment.

FIG. 5A is a diagram showing a configuration of a power converter 10A that is a comparative example.

FIG. 5B is a diagram showing the configuration of the power converter 10 according to the first embodiment.

FIG. 6 is a perspective view schematically showing a main part of a power converter 10B according to a second embodiment.

FIG. 7 is a diagram showing a configuration of the power converter 10B according to the second embodiment.

FIG. 8 is a diagram showing a flow path for a refrigerant in a cooler 100A included in the power converter 10B according to the second embodiment.

FIG. 9 is a perspective view schematically showing a main part of a power converter 10C according to a third embodiment.

FIG. 10 is a diagram showing a configuration of the power converter 10C according to the third embodiment.

FIG. 11 is a diagram showing an internal structure of a cooler 100B included in the power converter 10C according to the third embodiment.

FIG. 12 is a diagram showing a flow path for a refrigerant in the cooler 100B included in the power converter 10C according to the third embodiment.

FIG. 13 is a perspective view schematically showing a main part of a power converter 10D according to a fourth embodiment.

FIG. 14 is a diagram showing a configuration of the power converter 10D according to the fourth embodiment.

FIG. 15 is a diagram showing an internal structure of a cooler 100C included in the power converter 10D according to the fourth embodiment.

FIG. 16A is a diagram showing a flow path for a refrigerant in the cooler 100C included in the power converter 10D according to the fourth embodiment.

FIG. 16B is a diagram showing a flow path for a refrigerant in the cooler 100C included in the power converter 10D according to the fourth embodiment.

FIG. 17 is a diagram showing an internal structure of a cooler 100D included in a power converter 10E according to a modification.

### DESCRIPTION OF EMBODIMENTS

Embodiments according to the present disclosure will be described with reference to the drawings. In each drawing, dimensions and scales of elements may differ from those of actual products. The embodiments described below include various technical limitations. However, the scope of the present disclosure is not limited to the embodiments described below unless the following explanation includes a description that specifically limits the scope of the present disclosure.

### 1. First Embodiment

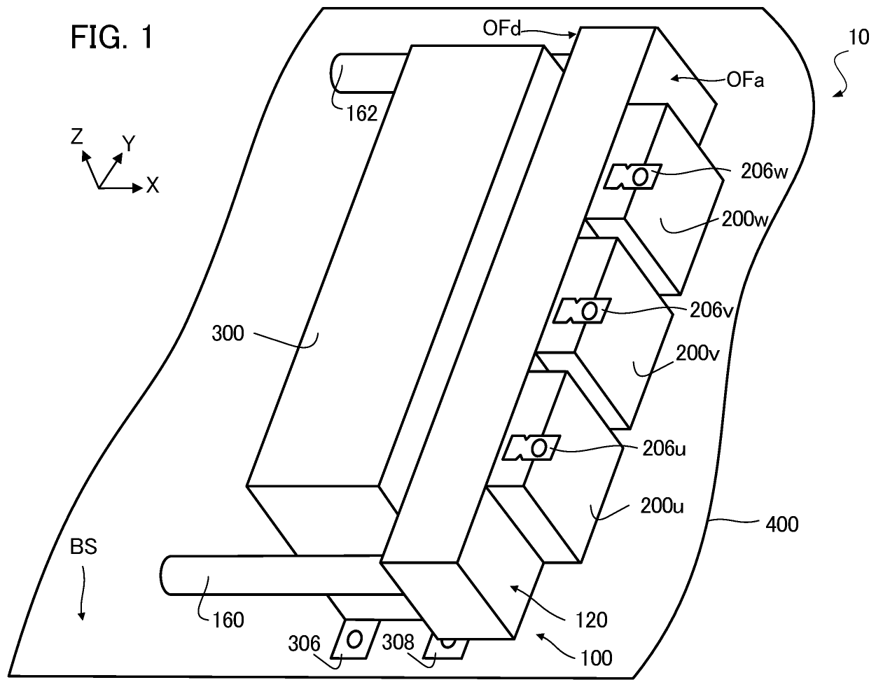

Embodiments according to the present disclosure will be described below. An example of an outline of a power converter 10 according to a first embodiment will be described with reference to FIG. 1.

### 1-1. Configuration of First Embodiment

FIG. 1 is a perspective view schematically showing a main part of the power converter 10 according to the first embodiment.

In the following description, a three-axis rectangular coordinate system having an X-axis, a Y-axis, and a Z-axis perpendicular to each other is defined for convenience of explanation. In the following description, a direction indicated by an arrow of the X-axis is referred to as the +X direction, and a direction opposing the +X direction is referred to as the −X direction. A direction indicated by an arrow of the Y-axis is referred to as the +Y direction, and a direction opposing the +Y direction is referred to as the −Y direction. A direction indicated by an arrow of the Z-axis is referred to as the +Z direction, and a direction opposing the +Z direction is referred to as the −Z direction. In the following description, the +Y direction and the −Y direction may be referred to as the Y direction without distinction therebetween, and the +X direction and the −X direction may be referred to as the X direction without distinction therebetween. The +Z direction and the −Z direction may be referred to as the Z direction without distinction therebetween.

The power converter 10 may be a freely selected power semiconductor device such as an inverter, a converter, etc. The power converter 10 is an example of a “semiconductor device.” In this embodiment, the power converter 10 is assumed to be a power semiconductor device that converts DC power, which is input to the power converter 10, into three-phase AC power having a U-phase, a V-phase, and a W-phase.

For example, the power converter 10 includes three semiconductor modules 200u, 200v, and 200w, a capacitor 300, and a cooler 100. The three semiconductor modules 200u, 200v, and 200w are configured to convert DC power to AC power. The capacitor 300 is configured to supply DC power to the semiconductor modules 200u, 200v, and 200w. The cooler 100 is configured to cool not only the semiconductor modules 200u, 200v, and 200w, but also the capacitor 300. The semiconductor modules 200u, 200v, and 200w, and the capacitor 300 are included in examples of a “heating element.” The power converter 10 further includes a housing 400. The housing 400 contains the capacitor 300, the cooler 100, and the semiconductor modules 200u, 200v, and 200w. The housing 400 includes a mounting surface BS. The mounting surface BS is parallel to an XY plane.

The semiconductor module 200u includes at least one semiconductor element. The semiconductor module 200u further includes input terminals 202u and 204u, which are described below, and an output terminal 206u, for example. The semiconductor module 200u converts DC power input to the input terminals 202u and 204u into U-phase AC power of three-phase AC power to output the U-phase AC power from the output terminal 206u, for example. Electric potential of the input terminal 202u is higher than that of the input terminal 204u, for example. Specifically, DC power includes P phase power and N phase power, and, for example, the P phase power is input to the input terminal 202u, whereas the N phase power is input to the input terminal 204u.

Each of the semiconductor modules 200v and 200w is similar to the semiconductor module 200u except for outputting V-phase AC power or W-phase AC power of three-phase AC power. For example, the semiconductor module 200v includes not only input terminals 202v and 204v, but also an output terminal 206v. In addition, the semiconductor module 200v outputs V-phase AC power from the output terminal 206v. The semiconductor module 200w includes not only input terminals 202w and 204w, but also an output terminal 206w. In addition, the semiconductor module 200w outputs W-phase AC power from the output terminal 206w, for example.

In the following description, the semiconductor modules 200u, 200v, and 200w may be generally referred to as semiconductor module 200. The input terminals 202u, 202v, and 202w may be generally referred to as input terminal 202. The input terminals 204u, 204v, and 204w may be generally referred to as input terminal 204. The output terminals 206u, 206v, and 206w may be generally referred to as output terminal 206. The number of semiconductor modules 200 included in the power converter 10 is not limited to three, and the power converter 10 may include two, four or more semiconductor modules 200.

The capacitor 300 is an element configured to store or emit power. The capacitor 300 does not have active functions such as amplification of power or conversion of electrical energy. In this embodiment, the capacitor 300 is used to drive the semiconductor modules 200u, 200v, and 200w. The capacitor 300 includes output terminals 302 and 304 described below. The output terminal 302 supplies DC power to the input terminal 202 included in the semiconductor module 200. Similarly, the output terminal 304 supplies DC power to the input terminal 204 included in the semiconductor module 200.

In an example shown in FIG. 1, the capacitor 300 is a structure having a shape of a rectangular parallelepiped extending in the Y direction. The capacitor 300 is mounted on the mounting surface BS included in the housing 400.

The cooler 100 includes a body 120 extending in the Y direction, a supply pipe 160 configured to supply a refrigerant to the body 120, and a drain pipe 162 configured to drain the refrigerant from the body 120. In this embodiment, it is assumed that the refrigerant is a liquid such as water.

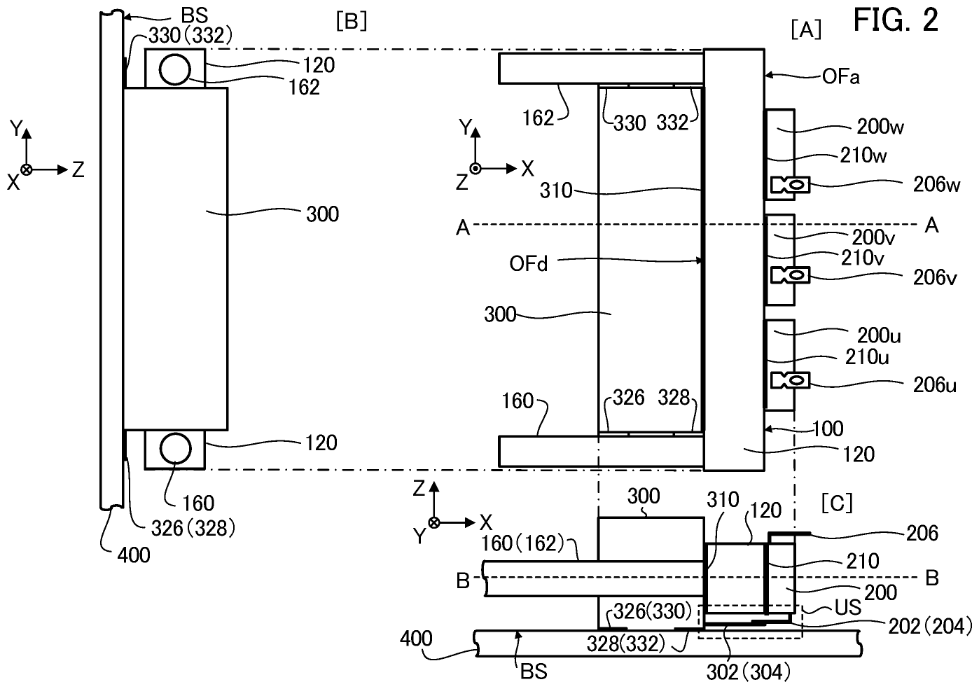

With reference to FIG. 1, an outline of the body 120 will be described. Details of the body 120 will be described with reference to FIGS. 2 to 4 below.

The body 120 is, for example, a hollow structure having a shape of a rectangular parallelepiped extending in the Y direction. The body 120 includes an outer surface OFa, on which the semiconductor modules 200 are mounted, and an outer surface OFd on which the capacitor 300 is mounted. The outer surface OFa is an example of a “first cooling surface.” The outer surface OFd is an example of a “second cooling surface.” In the example shown in FIG. 1, the outer surface OFa and the outer surface OFd are included in the body 120 having a shape of a rectangular parallelepiped. In addition, the outer surface OFa and the outer surface OFd oppose each other. Each of the outer surface OFa and the outer surface OFd is a plane parallel to a YZ plane. The outer surface OFa is spaced apart from the outer surface OFd in the +X direction.

The body 120 is formed of a material having excellent thermal conductivity. Examples of the material of the body 120 include a metal such as copper, aluminum, or an alloy of any thereof. The supply pipe 160 and the drain pipe 162 are formed of the same material as the body 120, for example. In other words, examples of a material of each of the supply pipe 160 and the drain pipe 162 include a metal such as copper, aluminum, or an alloy of any thereof. One, some, or all of the supply pipe 160 and the drain pipe 162 may be formed of a material different from that of the body 120.

The shape of the body 120 is not limited to the rectangular parallelepiped extending in the Y direction. For example, the shape of the body 120 in plan view in the −Y direction may be a shape having a curve. In other words, the outer surface OFa and the outer surface OFd may be curved.

Details of a configuration of the power converter 10 according to the first embodiment will be described with reference to FIG. 2.

FIG. 2 is a diagram showing the configuration of the power converter according to the first embodiment. FIG. 2 includes a diagram A that is a plan view of the power converter 10 shown in FIG. 1 viewed in the −Z direction, a diagram B that is a side view of the power converter 10 viewed in the +X direction, and a diagram C that is a side view of the power converter 10 viewed in the +Y direction.

As shown in the diagram A of FIG. 2, the three semiconductor modules 200u, 200v, and 200w are spaced apart from each other in the Y direction that is a longitudinal direction of the cooler 100. The semiconductor module 200 includes a bottom surface parallel to the XY plane. The bottom surface of the semiconductor module 200 is coupled to the outer surface OFa that is the first cooling surface of the cooler 100. Between the semiconductor module 200 and the outer surface OFa, a thermal interface material (TIM) 210, such as a thermally conductive grease, a thermally conductive adhesive, a thermally conductive sheet, and solder, is interposed. More specifically, a TIM 210u is interposed between the semiconductor module 200u and the outer surface OFa. Similarly, a TIM 210v is interposed between the semiconductor module 200v and the outer surface OFa. In addition, a TIM 210w is interposed between the semiconductor module 200w and the outer surface OFa.

The capacitor 300 is coupled to the outer surface OFd that is the second cooling surface of the cooler 100. Between the capacitor 300 and the outer surface OFd, a TIM 310, such as a thermally conductive grease, a thermally conductive adhesive, a thermally conductive sheet, and solder, is interposed.

In an example shown in FIG. 2, the overall length of the semiconductor modules 200 in the Y direction is less than the length of the body 120 included in the cooler 100 in the Y direction. In addition, an overall side of the semiconductor modules 200 along the Y direction is not away from a side of the body 120 along the Y direction. In the example shown in FIG. 2, the width of the semiconductor module 200 in the Z direction is equal to the width of the body 120 included in the cooler 100 in the Z direction. However, this is just an example. Preferably, the width of the semiconductor module 200 in the Z direction is less than the width of the body 120 in the Z direction. Thus, the entire bottom surface of the semiconductor module 200 parallel to the YZ plane is cooled by the cooler 100.

In addition, in the example shown in FIG. 2, the length of the capacitor 300 in the Y direction is less than the length of the body 120 included in the cooler 100 in the Y direction. In addition, a side of the capacitor 300 along the Y direction is not away from a side of the body 120 along the Y direction. In the example shown in FIG. 2, the body 120 is positioned at a substantially center portion of the capacitor 300 in the Z direction. However, this is just an example. The body 120 may be positioned at a freely selected portion of the capacitor 300 in the Z direction. In the example shown in FIG. 2, the width of the capacitor 300 in the Z direction is greater than the width of the body 120 included in the cooler 100 in the Z direction. However, this is just an example. For example, the width of the capacitor 300 in the Z direction may be equal to the width of the body 120 in the Z direction.

In the power converter 10 shown in FIG. 1, a plurality of semiconductor modules 200 is arrayed in the longitudinal direction of the cooler 100. According to this configuration, it is possible to reduce the size of the power converter 10 in the X direction as compared to a configuration in which a plurality of sets of the semiconductor module 200 and the cooler 100 are stacked on an outer surface of the capacitor 300.

A stacking direction of stacking of the capacitor 300, the cooler 100, and the semiconductor module 200 is the X direction. In other words, the stacking direction is parallel to the mounting surface BS of the housing 400.

The supply pipe 160 and the drain pipe 162 are coupled to the outer surface OFd that is the second cooling surface of the cooler 100. The supply pipe 160 and the drain pipe 162 are each a pipe extending in the X direction. More specifically, the outer surface OFd included in the cooler 100 has two end portions that are not in contact with the capacitor 300. The supply pipe 160 is coupled to one end portion of the outer surface OFd in the —Y direction among the two end portions of the outer surface OFd. On the other hand, the drain pipe 162 is coupled to the other end portion of the outer surface OFd in the +Y direction among the two end portions of the outer surface OFd.

As shown in the diagram B of FIG. 2, the capacitor 300 is fixed to the mounting surface BS included in the housing 400 by mounting portions 326, 328, 330, and 332. The mounting portions 326, 328, 330, and 332 each have a hole into which a screw or a bolt is inserted. The capacitor 300 is fixed to the housing 400 by tightening the screw or the bolt.

The cooler 100 is fixed to the housing 400 by sandwiching two ends of the cooler 100 in the Y direction with the housing 400.

As shown in the diagram C of FIG. 2, a space US is provided not only between the semiconductor module 200 and the mounting surface BS, but also between the cooler 100 and the mounting surface BS. The output terminals 302 and 304 included in the capacitor 300 and the input terminals 202 and 204 included in the semiconductor module 200 are positioned in the space US. In the space US, the output terminal 302 and the input terminal 202 are electrically connected to each other. Similarly, the output terminal 304 and the input terminal 204 are electrically connected to each other. The output terminal 302, the input terminal 202, the output terminal 304, and the input terminal 204 are each an example of a conductor. The output terminal 302 and the input terminal 202 may be in contact with each other, and the output terminal 304 and the input terminal 204 may be in contact with each other, and then the output terminal 302 and the input terminal 202 may be fixed to each other by screw or by bolt, and the output terminal 304 and the input terminal 204 may be fixed to each other by screw or by bolt, for example. These electrical connections allow DC power to be supplied from the capacitor 300 to the semiconductor module 200. The space US, which is provided not only between the semiconductor module 200 and the mounting surface BS, but also between the cooler 100 and the mounting surface BS, is effectively used as a space for installing conductors for electrically connecting each of the semiconductor modules 200 and the capacitor 300 to each other.

Instead of a configuration shown in the diagram C of FIG. 2, a configuration may be used in which the space US is not provided. Specifically, a configuration may be used in which the semiconductor module 200 and the cooler 100 are in contact with the mounting surface BS. In this case, for example, a configuration may be used in which the cooler 100 has a through hole extending in the X direction. The through hole contains the output terminal 302, the input terminal 202, the output terminal 304, and the input terminal 204.

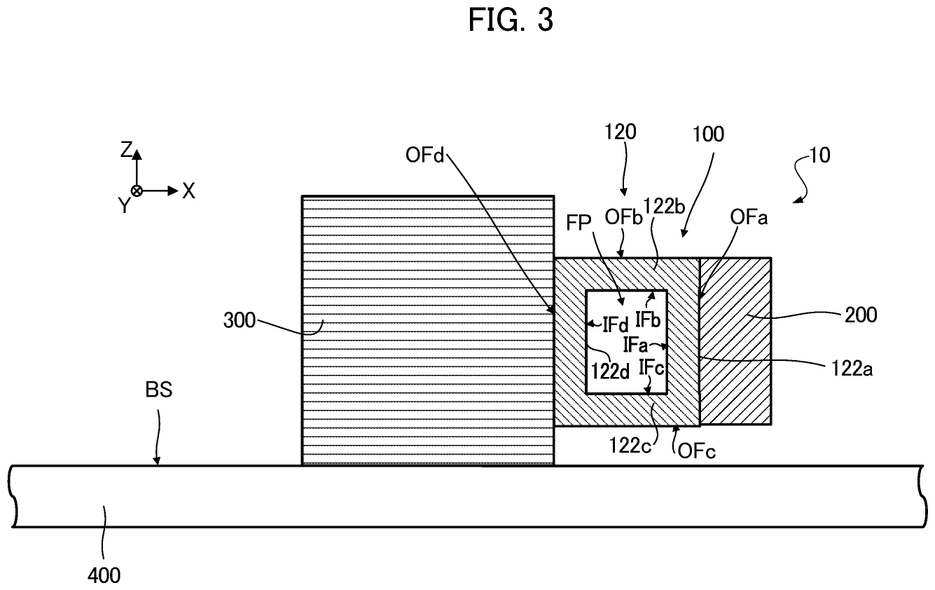

An internal structure of the cooler 100 included in the power converter 10 according to the first embodiment will be described with reference to FIG. 3.

FIG. 3 is a diagram showing the internal structure of the cooler 100 included in the power converter 10 according to the first embodiment. Specifically, FIG. 3 is a cross section of the power converter 10 in an XZ plane passing through a straight line A shown in FIG. 2.

The body 120 included in the cooler 100 includes outer walls 122a, 122b, 122c, and 122d. In a rectangle defined by a cross section of the body 120, the outer wall 122a is spaced apart from the outer wall 122d in the +X direction. The outer wall 122b is spaced apart from the outer wall 122c in the +Z direction. The outer wall 122c is spaced apart from the outer wall 122b in the −Z direction. The outer wall 122d is spaced apart from the outer wall 122a in the −X direction. The outer walls 122a to 122d each extend in the Y direction. The outer wall 122a is an example of a “first wall.” The outer wall 122d is an example of a “second wall.”

The body 120 further includes outer walls 122e and 122f (not shown in FIG. 3) that are described below. The outer wall 122e is spaced apart from the outer wall 122f in the −Y direction. The outer wall 122e extends in the Z direction. The outer wall 122f is spaced apart from the outer wall 122e in the +Y direction. The outer wall 122f extends in the Z direction. As described above, the body 120 is a rectangular parallelepiped extending in the Y direction. The outer wall 122e includes an end surface of the body 120 in the −Y direction. On the other hand, the outer wall 122f includes an end surface of the body 120 in the +Y direction. In this embodiment, the thicknesses of the outer walls 122a to 122f are equal to each other.

The semiconductor module 200 is mounted on the outer wall 122a. The outer wall 122a includes the outer surface OFa, on which the semiconductor module 200 is mounted, and an inner surface IFa opposing the outer surface OFa. The inner surface IFa is an example of an “inner wall surface.” The outer wall 122b includes an outer surface OFb and an inner surface IFb opposing the outer surface OFb. The outer wall 122c includes an outer surface OFc and an inner surface IFc opposing the outer surface OFc. The outer wall 122d includes the outer surface OFd, on which the capacitor 300 is mounted, and an inner surface IFd opposing the outer surface OFd. By the inner surface IFa, IFb, IFc, and IFd, a flow path FP for a refrigerant is defined. The flow path FP for a refrigerant is a flow path extending in the Y direction. In other words, in a direction in which the refrigerant flows, the plurality of semiconductor modules 200 is arrayed.

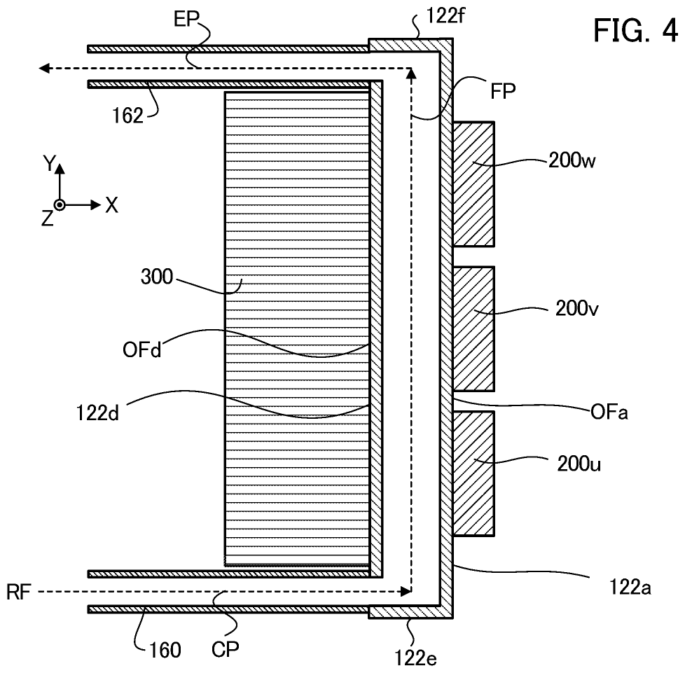

The flow path for a refrigerant in the cooler 100 included in the power converter 10 according to the first embodiment will be described with reference to FIG. 4.

FIG. 4 is a diagram showing the flow path for a refrigerant in the cooler 100 included in the power converter 10 according to the first embodiment. Specifically, FIG. 4 is a cross section of the power converter in an XY plane passing through a straight line B shown in FIG. 2.

In FIG. 4, the supply pipe 160 has a supply path CP configured to supply a refrigerant RF to the body 120 of the cooler 100. The supply path CP is a flow path extending in the X direction. The supply path CP communicates with the flow path FP. On the other hand, the drain pipe 162 has a drain path EP configured to drain the refrigerant RF from the body 120. The drain path EP is a flow path extending in the X direction. The drain path EP communicates with the flow path FP.

The refrigerant RF for flowing through the cooler 100 is supplied to the body 120 of the cooler 100 through the supply path CP of the supply pipe 160. The refrigerant RF then flows in the flow path FP of the body 120 in the +Y direction. While flowing in the +Y direction, the refrigerant RF cools the semiconductor module 200 via the outer surface OFa that is an example of the first cooling surface. In addition, the refrigerant RF cools the capacitor 300 via the outer surface OFd that is an example of the second cooling surface. Finally, the refrigerant RF is drained from the body 120 of the cooler 100 through the drain path EP of the drain pipe 162.

### 1-2. Comparative Example

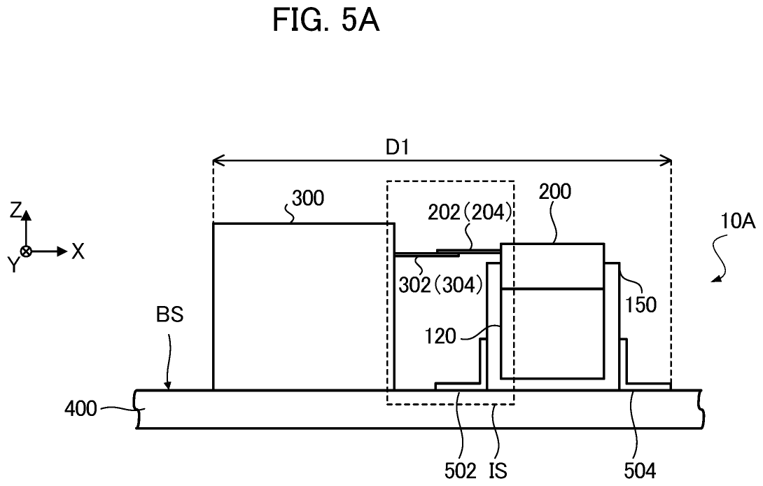

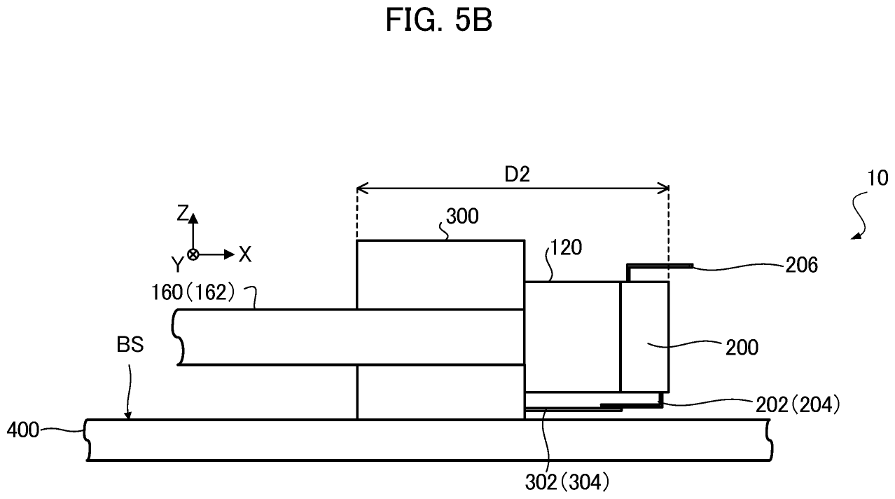

With reference to FIG. 5A and FIG. 5B, a configuration of a power converter 10A, which is a comparative example, will be described while being compared to the configuration of the power converter 10 according to the first embodiment.

FIG. 5A is a diagram showing the configuration of the power converter 10A that is the comparative example. FIG. 5B is a diagram showing the configuration of the power converter 10 according to the first embodiment. FIG. 5A is a side view of the power converter 10A viewed in the +Y direction. FIG. 5B is a side view of the power converter 10 viewed in the +Y direction. FIG. 5B is the same as the diagram C of FIG. 2.

As shown in FIG. 5A, apart from the capacitor 300, the body 120 of the cooler 100 and the semiconductor module 200 are mounted on the mounting surface BS in the power converter 10A. More specifically, a head 150, which contains the body 120 and the semiconductor module 200, is fixed to the mounting surface BS by mounting portions 502 and 504. Within the head 150, the body 120 is stacked on the semiconductor module 200 in the −Z direction, and the semiconductor module 200 is stacked on the body 120 in the +Z direction. There is substantially no gap between the head 150 and the body 120, and also substantially no gap between the head 150 and the semiconductor module 200.

A space IS is provided between the capacitor 300 and the head 150 containing the body 120 and the semiconductor module 200. The output terminals 302 and 304 included in the capacitor 300 and the input terminals 202 and 204 included in the semiconductor module 200 are positioned in the space IS. In the space IS, the output terminal 302 and the input terminal 202 are electrically connected to each other. Similarly, the output terminal 304 and the input terminal 204 are electrically connected to each other.

In comparing the power converter 10A, which is the comparative example, with the power converter 10 according to the first embodiment, a width D1 of the power converter 10A in the X direction is greater than a width D2 of the power converter 10 in the X direction. This is because, as described above, the power converter 10A needs the space IS between the capacitor 300 and the head 150. In the space IS, the output terminal 302, the output terminal 304, the input terminal 202, and the input terminal 204 are positioned so as to supply DC power from the capacitor 300 to the semiconductor module 200.

On the other hand, in this embodiment, the capacitor 300, the cooler 100, and the semiconductor module 200 are stacked in a direction parallel to the mounting surface BS. This allows the capacitor 300 and the cooler 100 to be coupled to each other without gaps. Accordingly, the capacitor 300 can be cooled by the cooler 100. In particular, the cooler 100 can be used to cool not only the semiconductor module 200, but also the capacitor 300. This simplifies the configuration of the power converter 10 compared to that of the power converter 10A. In addition, the size of the power converter 10 in the X direction that is the direction parallel to the mounting surface BS is reduced.

### 1-3. Effects of First Embodiment

The power converter 10, which is an example of a semiconductor device according to this embodiment, includes the elongated cooler 100 through which the refrigerant RF flows, the plurality of semiconductor modules 200 each of which includes one or more semiconductor elements, and the capacitor 300 configured to drive the plurality of semiconductor modules 200. The cooler 100 includes the outer surface OFa, which is an example of the first cooling surface, and the outer surface OFd, which is an example of the second cooling surface opposing the first cooling surface. The plurality of semiconductor modules 200 is arrayed in the longitudinal direction of the cooler 100. The plurality of semiconductor modules 200 is coupled to the first cooling surface. The capacitor 300 is coupled to the second cooling surface.

According to the configuration described above, it is possible to increase the cooling efficiency of the capacitor 300 without increasing the size of the power converter 10 in the stacking direction as compared to the prior art. Specifically, the plurality of semiconductor modules 200 is arrayed in the longitudinal direction of the cooler 100. According to this configuration, it is possible to reduce the size of the semiconductor device in a direction perpendicular to the first cooling surface or the second cooling surface, as compared to a configuration in which a plurality of sets of the semiconductor module 200 and the cooler 100 are stacked on an outer surface of the capacitor 300. The capacitor 300 and the cooler 100 are coupled to each other without gaps. Accordingly, the capacitor 300 can be cooled by the cooler 100. In particular, the cooler 100 can be used to cool not only the semiconductor module 200 but also the capacitor 300. As a result, the configuration of the power converter 10 can be simplified.

The power converter 10, which is an example of a semiconductor device, further includes the housing 400. The housing 400 contains the capacitor 300, the cooler 100, and the plurality of semiconductor modules 200. The housing 400 includes the mounting surface BS on which the capacitor 300 is mounted. The stacking direction of stack of the capacitor 300, the cooler 100, and the semiconductor module 200 is parallel to the mounting surface BS.

If the capacitor 300 is mounted on the mounting surface BS of the housing 400 in a situation in which, separated from the capacitor 300, the cooler 100 and the semiconductor module 200 are stacked on the mounting surface BS of the housing 400 in a direction perpendicular to the mounting surface BS of the housing 400, a space, in which terminals are disposed, is required between the capacitor 300 and the semiconductor module 200. Consequently, the capacitor 300 and the cooler 100 cannot be coupled to each other. In contrast, according to the configuration of this embodiment described above, by arranging the capacitor 300, the cooler 100, and the semiconductor module 200 in parallel with the mounting surface BS, the capacitor 300 and the cooler 100 can be coupled to each other, thereby increasing the cooling efficiency of the power converter 10.

In addition, in the power converter 10, which is an example of a semiconductor device, the space US is provided not only between the plurality of semiconductor modules 200 and the mounting surface BS, but also between the cooler 100 and the mounting surface BS. A conductor electrically connecting the plurality of semiconductor modules 200 and the capacitor 300 to each other is positioned in the space US.

According to the configuration described above, the space US is provided not only between each semiconductor module 200 and the mounting surface BS, but also between the cooler 100 and the mounting surface BS. The space US can be effectively used as a space for installing conductors electrically connecting each semiconductor module 200 and the capacitor 300 to each other.

### 2. Second Embodiment

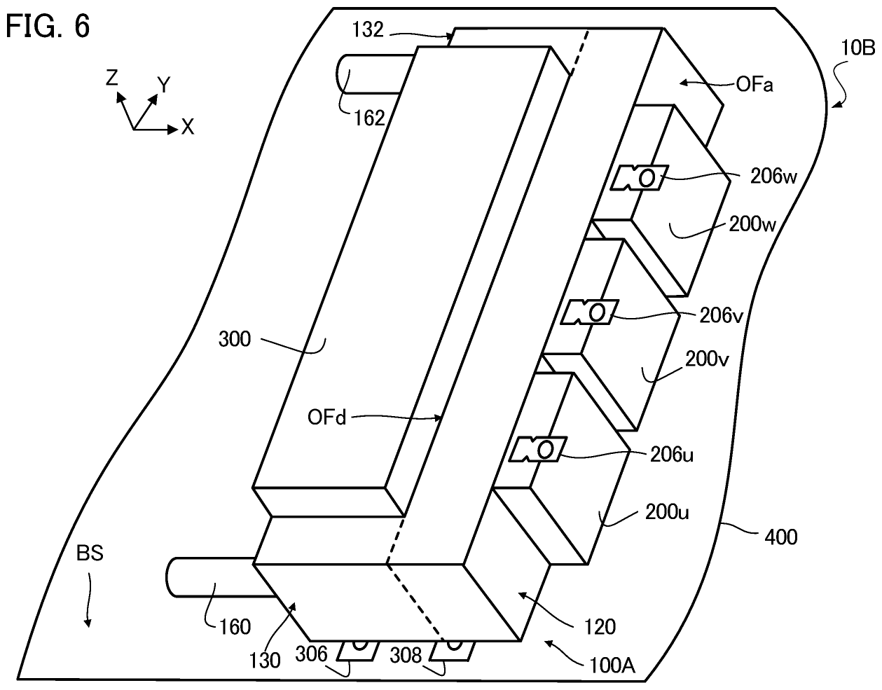

An example of an outline of a power converter 10B according to a second embodiment will be described with reference to FIG. 6. In the following description, to facilitate explanation, among elements of the power converter 10B according to the second embodiment, elements substantially the same as the elements of the power converter 10 according to the first embodiment are denoted with like reference signs, and detailed explanations thereof may be omitted. The following will mainly explain differences between the power converter 10B according to the second embodiment and the power converter 10 according to the first embodiment.

### 2-1. Configuration of Second Embodiment

FIG. 6 is a perspective view schematically showing a main part of the power converter 10B according to the second embodiment. The power converter 10B includes a cooler 100A instead of the cooler 100 included in the power converter 10 according to the first embodiment. The cooler 100A includes a first head 130 and a second head 132 in addition to the body 120, the supply pipe 160, and the drain pipe 162.

The first head 130 is in contact with an end portion of the body 120 in the −Y direction. The end portion of the body 120 in the −Y direction is an example of a “first end portion.” The first head 130 is a hollow structure having a shape of a rectangular parallelepiped extending in the X direction. One end of the first head 130 is in contact with the first end portion, whereas the other end of the first head 130 is in contact with the supply pipe 160. A surface of the first head 130 in the +Y direction is coupled to a surface of the capacitor 300 in the −Y direction. Furthermore, as described below, a first flow path FP1, which communicates with a second flow path FP2 in the body 120, is formed inside the first head 130.

The second head 132 is in contact with an end portion of the body 120 in the +Y direction. The end portion of the body 120 in the +Y direction is an example of a “second end portion.” The second head 132 is a hollow structure having a shape of a rectangular parallelepiped extending in the X direction. One end of the second head 132 is in contact with the second end portion, whereas the other end of the second head 132 is in contact with the drain pipe 162. A surface of the second head 132 in the −Y direction is coupled to a surface of the capacitor 300 in the +Y direction. Furthermore, as described below, a third flow path FP3, which communicates with the second flow path FP2 in the body 120, is formed inside the second head 132.

The first head 130 and the second head 132 may be formed integrally with the body 120.

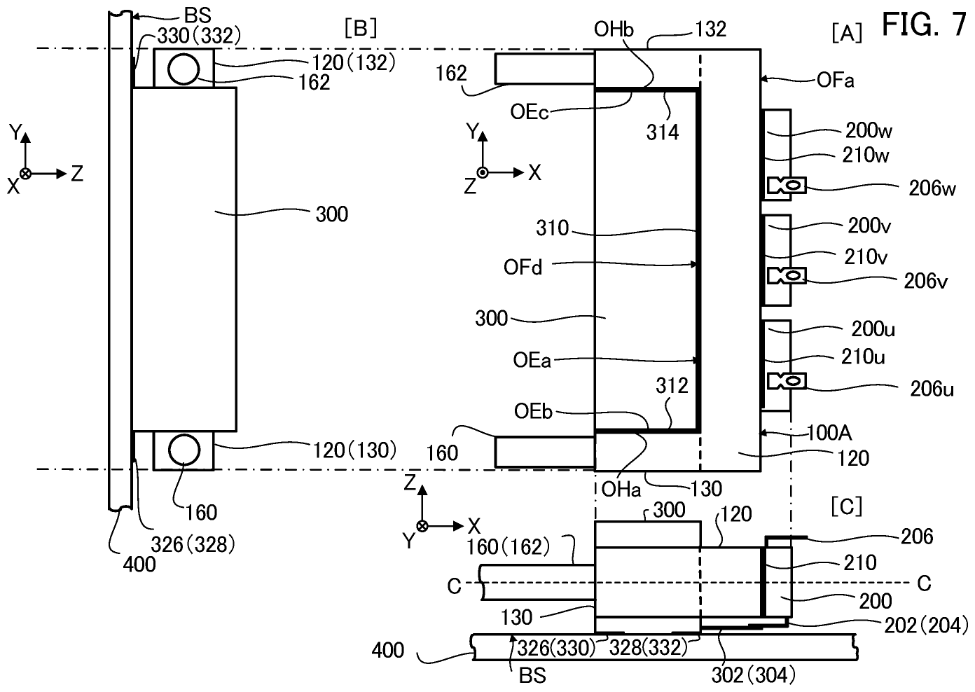

Details of a configuration of the power converter 10B according to the second embodiment will be described with reference to FIG. 7.

FIG. 7 is a diagram showing the configuration of the power converter 10B according to the second embodiment. FIG. 7 includes a diagram A that is a plan view of the power converter 10B shown in FIG. 6 viewed in the −Z direction, a diagram B that is a side view of the power converter 10B viewed in the +X direction, and a diagram C that is a side view of the power converter 10B viewed in the +Y direction.

As shown in the diagram A of FIG. 7, the capacitor 300 includes an outer surface OEa, an outer surface OEb, and an outer surface OEc. The outer surface OEa faces the outer surface OFd that is an example of the second cooling surface included in the cooler 100A. The outer surface OEb faces the first head 130. The outer surface OEc faces the second head 132. The outer surface OEa is an example of a “first element surface.” The outer surface OEb is an example of a “second element surface.” The outer surface OEc is an example of a “third element surface.”

The first head 130 includes an outer surface OHa. The outer surface OHa faces the outer surface OEb of the capacitor 300. The outer surface OHa is an example of a “third cooling surface.” The outer surface OHa, which is an example of the third cooling surface, is coupled to the outer surface OEb that is an example of the second element surface. Between the outer surface OHa and the outer surface OEb, a TIM 312, such as a thermally conductive grease, a thermally conductive adhesive, a thermally conductive sheet, and solder, is interposed.

According to the configuration described above, in addition to the outer surface OEa of the capacitor 300, the outer surface OEb is cooled by the cooler 100A. Therefore, the cooling efficiency of the capacitor 300 can be increased as compared to a configuration in which only the outer surface OEa is coupled to the cooler 100A.

The second head 132 includes an outer surface OHb. The outer surface OHb faces the outer surface OEc of the capacitor 300. The outer surface OHb is an example of a “fourth cooling surface.” The outer surface OHb, which is an example of the fourth cooling surface, is coupled to the outer surface OEc that is an example of the third element surface. Between the outer surface OHb and the outer surface OEc, a TIM 314, such as a thermally conductive grease, a thermally conductive adhesive, a thermally conductive sheet, and solder, is interposed.

According to the configuration described above, in addition to the outer surfaces OEa and OEb of the capacitor 300, the outer surface OEc is cooled by the cooler 100A. In other words, the capacitor 300 is cooled from three directions by the cooler 100A. Therefore, the cooling efficiency of the capacitor 300 can be increased as compared to a configuration in which only the outer surfaces OEa and OEb are coupled to the cooler 100A.

In FIG. 7, the width of the first head 130 in the Z direction and the width of the second head 132 in the Z direction are equal to the width of the body 120 in the Z direction. However, this is just an example. The width of the first head 130 in the Z direction and the width of the second head 132 in the Z direction may be freely selected, unless there is a practical problem. In FIG. 7, the width of the first head 130 in the X direction and the width of the second head 132 in the X direction are equal to the width of the capacitor 300 in the X direction. However, this is just an example. The width of the first head 130 in the X direction and the width of the second head 132 in the X direction may be freely selected, unless there is a practical problem.

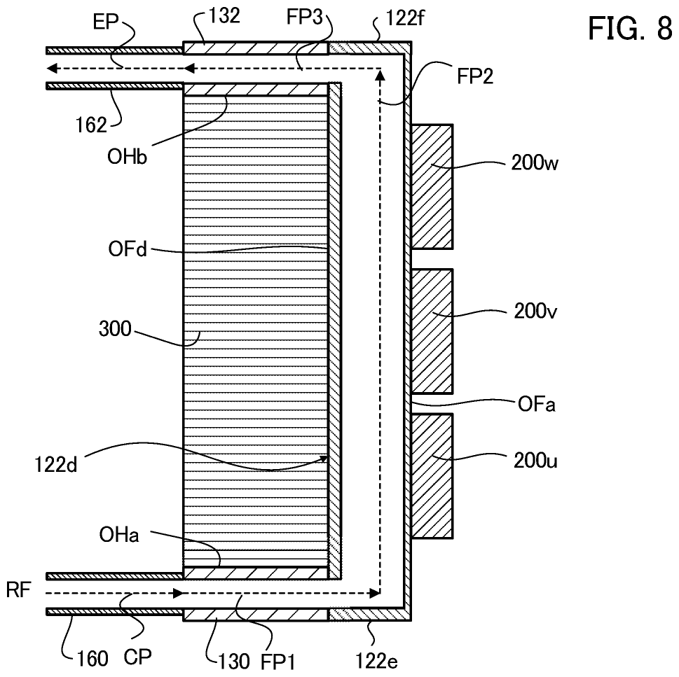

A flow path for a refrigerant in the power converter 10B according to the second embodiment will be described with reference to FIG. 8. Specifically, a flow path for a refrigerant in the first head 130, a flow path for a refrigerant in the cooler 100 of the power converter 10B, and a flow path for a refrigerant in the second head 132 will be described with reference to FIG. 8.

FIG. 8 is a diagram showing the flow path for a refrigerant in the cooler 100A included in the power converter 10B according to the second embodiment. Specifically, FIG. 8 is a cross section of the power converter 10B in an XY plane passing through a straight line C shown in FIG. 7.

A refrigerant RF for flowing through the cooler 100A is supplied to the first head 130 through the supply path CP of the supply pipe 160. The refrigerant RF then flows in the first flow path FP1 of the first head 130 in the +X direction. While flowing in the +X direction, the refrigerant RF cools the capacitor 300 via the outer surface OHa that is an example of the third cooling surface. The refrigerant RF is then supplied to the body 120 of the cooler 100A to flow in the second flow path FP2 of the body 120 in the +Y direction. While flowing in the +Y direction, the refrigerant RF cools the semiconductor module 200 via the outer surface OFa, which is an example of the first cooling surface. In addition, the refrigerant RF cools the capacitor 300 via the outer surface OFd, which is an example of the second cooling surface. The refrigerant RF is then supplied to the second head 132 to flow in the third flow path FP3 of the second head 132 in the −X direction. While flowing in the −X direction, the refrigerant RF cools the capacitor 300 via the outer surface OHb, which is an example of the fourth cooling surface. Finally, the refrigerant RF is drained from the body 120 of the cooler 100A through the drain path EP of the drain pipe 162.

### 2-2. Effects of Second Embodiment

In the power converter 10B, which is an example of the semiconductor device according to this embodiment, the capacitor 300 includes the outer surface OEa and the outer surface OEb. The outer surface OEa, which is an example of the first element surface, is coupled to the outer surface OFd that is an example of the second cooling surface. The outer surface OEb, which is an example of the second element surface, is one end surface of the capacitor 300 in the longitudinal direction of the cooler 100A. The cooler 100A includes the body 120 that includes the outer surface OFa, which is an example of the first cooling surface, and the outer surface OFd, which is an example of the second cooling surface. The cooler 100A includes the first head 130. The first head 130 is in contact with the first end portion of the body 120. The first head 130 includes the first flow path FP1 that communicates with the second flow path FP2 inside the body 120. The first head 130 includes the outer surface OHa. The outer surface OHa, which is an example of the third cooling surface, is a plane that faces the outer surface OEb, which is an example of the second element surface. The outer surface OHa, which is an example of the third cooling surface, is coupled to the outer surface OEb, which is an example of the second element surface.

According to the configuration described above, in addition to the first element surface of the capacitor 300, the second element surface is cooled by the cooler 100A. Therefore, the cooling efficiency of the capacitor 300 can be increased compared to a configuration in which only the first element surface is coupled to the cooler 100A.

Furthermore, in the power converter 10B, which is an example of the semiconductor device according to this embodiment, the capacitor 300 further includes the outer surface OEc. The outer surface OEc, which is an example of the third element surface, is opposing the outer surface OEb, which is an example of the second element surface. The cooler 100A further includes the second head 132. The second head 132 is in contact with the second end portion of the body 120. The second end portion of the body 120 is opposing the first end portion of the body 120. The second head 132 includes the third flow path FP3, which communicates with the second flow path FP2 inside the body 120. The second head 132 includes the outer surface OHb. The outer surface OHb, which is an example of the fourth cooling surface, is a plane that faces the outer surface OEc, which is an example of the third element surface. The fourth cooling surface is coupled to the outer surface OEc, which is an example of the third element surface.

According to the configuration described above, in addition to the first element surface and the second element surface of the capacitor 300, the third element surface is cooled by the cooler 100A. In other words, the capacitor 300 is cooled from three directions by the cooler 100A. Therefore, the cooling efficiency of the capacitor 300 can be increased compared to a configuration in which only both the first element surface and the second element surface are coupled to the cooler 100A.

### 3. Third Embodiment

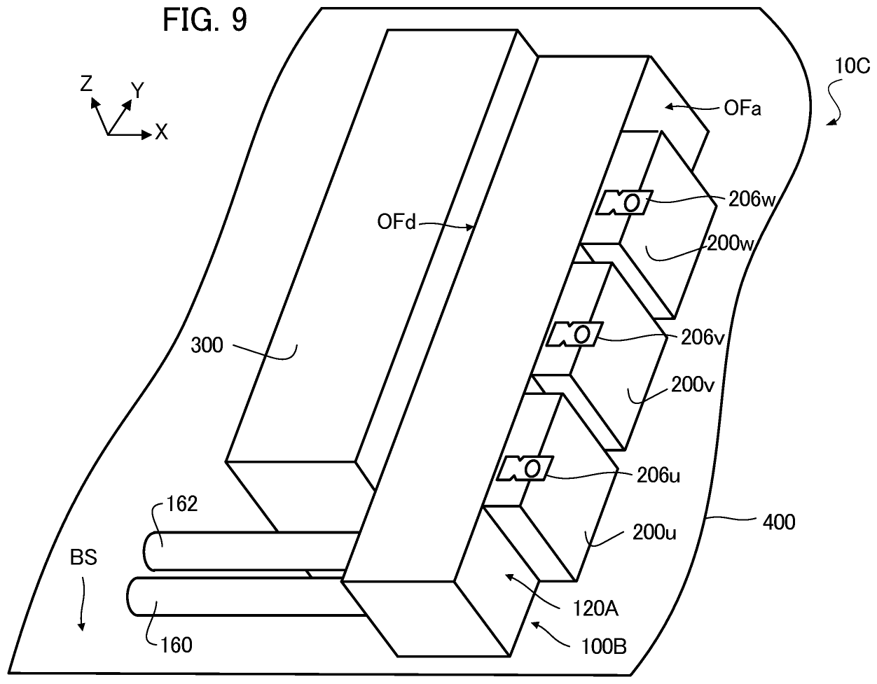

An example of an outline of a power converter 10C according to a third embodiment will be described with reference to FIG. 9. In the following description, to facilitate explanation, among elements of the power converter 10C according to the third embodiment, elements substantially the same as the elements of the power converter 10 according to the first embodiment are denoted with like reference signs, and detailed explanations thereof may be omitted. The following will mainly explain differences between the power converter 10C according to the third embodiment and the power converter 10 according to the first embodiment.

### 3-1. Configuration of Third Embodiment

FIG. 9 is a perspective view schematically showing a main part of the power converter 10C according to the third embodiment. The power converter 10C, which is different from the power converter 10 according to the first embodiment, includes a cooler 100B instead of the cooler 100. In the power converter 10 according to the first embodiment, the supply pipe 160 is coupled to one end portion of the outer surface OFd included in the cooler 100 in the −Y direction among the two end portions of the outer surface OFd that are not in contact with the capacitor 300. In addition, in the power converter 10 according to the first embodiment, the drain pipe 162 is coupled to the other end portion of the outer surface OFd in the +Y direction among the two end portions. In contrast, in the power converter 10C according to the third embodiment, both the supply pipe 160 and the drain pipe 162 are coupled to an end portion of the outer surface OFd included in the cooler 100B in the −Y direction. Alternatively, both the supply pipe 160 and the drain pipe 162 may be coupled to the end portion of the outer surface OFd in the +Y direction instead of the end portion of the outer surface OFd in the −Y direction. Although not shown in FIG. 9, the cooler 100B, which is different from the cooler 100 according to the first embodiment, includes a first flow path FP4 that extends in a longitudinal direction of the cooler 100B, and a second flow path FP5 that extends in the longitudinal direction of the cooler 100B, as described below. The supply pipe 160 communicates with the first flow path FP4. On the other hand, the drain pipe 162 communicates with the second flow path FP5.

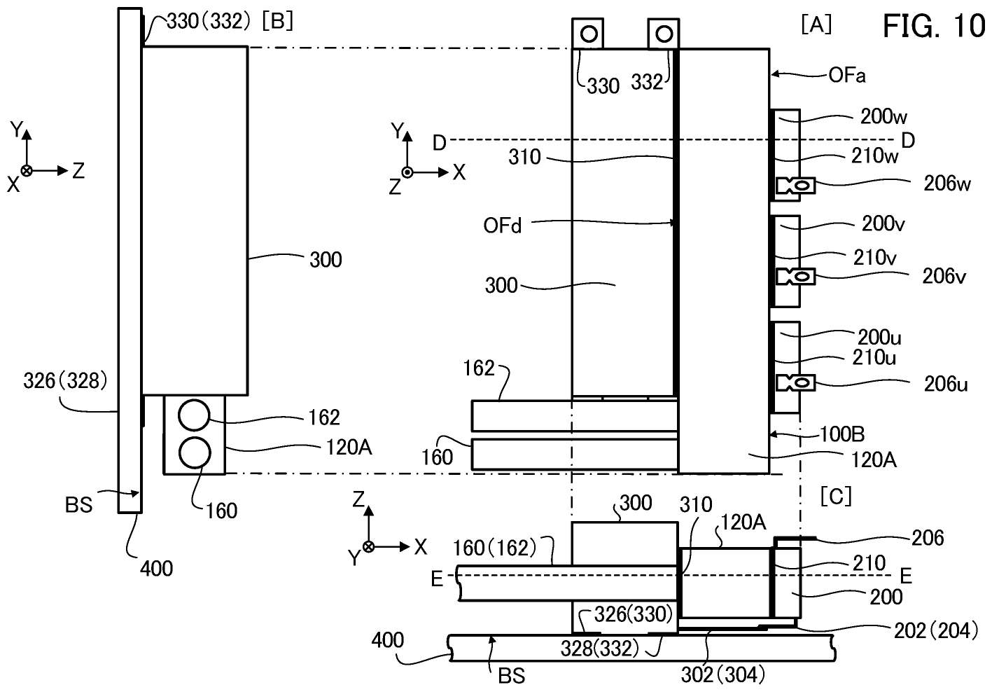

Details of a configuration of the power converter 10C according to the third embodiment will be described with reference to FIG. 10.

FIG. 10 is a diagram showing the configuration of the power converter 10C according to the third embodiment. FIG. 10 includes a diagram A that is a plan view of the power converter 10C shown in FIG. 9 viewed in the −Z direction, a diagram B that is a side view of the power converter 10C viewed in the +X direction, and a diagram C that is a side view of the power converter 10C viewed in the +Y direction.

As shown in FIG. 10, the supply pipe 160 is spaced apart from the drain pipe 162 in the −Y direction. However, this is just an example. The supply pipe 160 may be spaced apart from the drain pipe 162 in the +Y direction. The supply pipe 160 and the drain pipe 162 may be spaced apart from each other by a freely selected distance as long as the supply pipe 160 and the drain pipe 162 are positioned on an end portion of the outer surface OFd in the −Y direction.

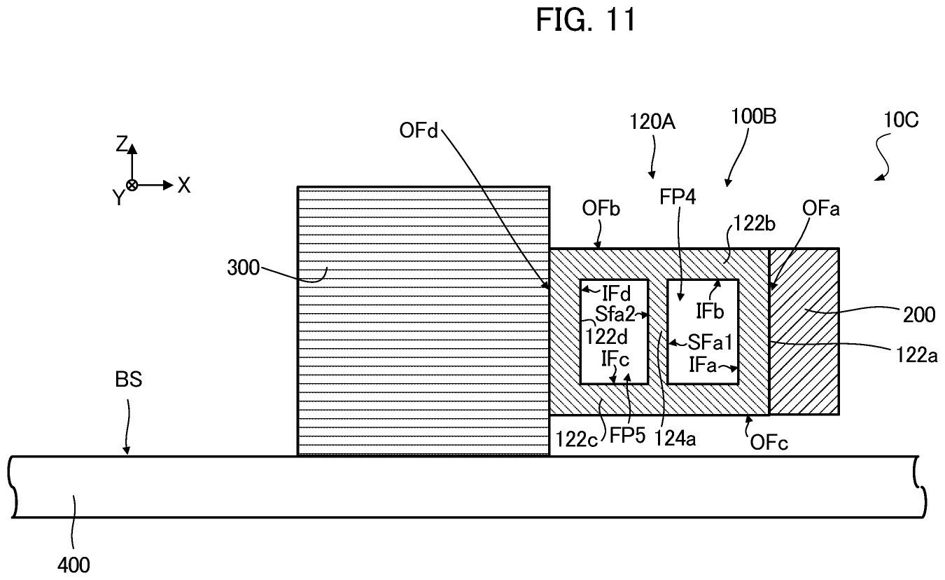

An internal structure of the cooler 100B included in the power converter 10C according to the third embodiment will be described with reference to FIG. 11.

FIG. 11 is a diagram showing the internal structure of the cooler 100B included in the power converter 10C according to the third embodiment. Specifically, FIG. 11 is a cross section of the power converter 10C in an XZ plane passing through a straight line D shown in FIG. 10.

A body 120A included in the cooler 100B, as well as the body 120 included in the cooler 100 according to the first embodiment, includes the outer walls 122a, 122b, 122c, and 122d.

The body 120A further includes a partition 124a. The partition 124a is coupled to the outer wall 122b and the outer wall 122c. Thus, the partition 124a divides a space, which is defined by the outer walls 122a, 122b, 122c, and 122d, into two spaces. The partition 124a includes a surface SFa1 that faces the inner surface IFa, and a surface SFa2 that faces the inner surface IFd. The first flow path FP4 is defined by the inner surfaces IFa, IFb, and IFc and the surface SFa1. The second flow path FP5 is defined by the surface SFa2 and the inner surfaces IFb, IFc, and IFd. In other words, the first flow path FP4 is closer to the semiconductor module 200 than the second flow path FP5.

The amount of heat generated by the semiconductor module 200 is usually more than the amount of heat generated by the capacitor 300. Thus, it is necessary to preferentially cool the semiconductor module 200. The first flow path FP4, through which a lower temperature refrigerant RF flows, is closer to the semiconductor module 200 than the second flow path FP5, through which a higher temperature refrigerant RF flows. Therefore, the semiconductor module 200 can be preferentially cooled.

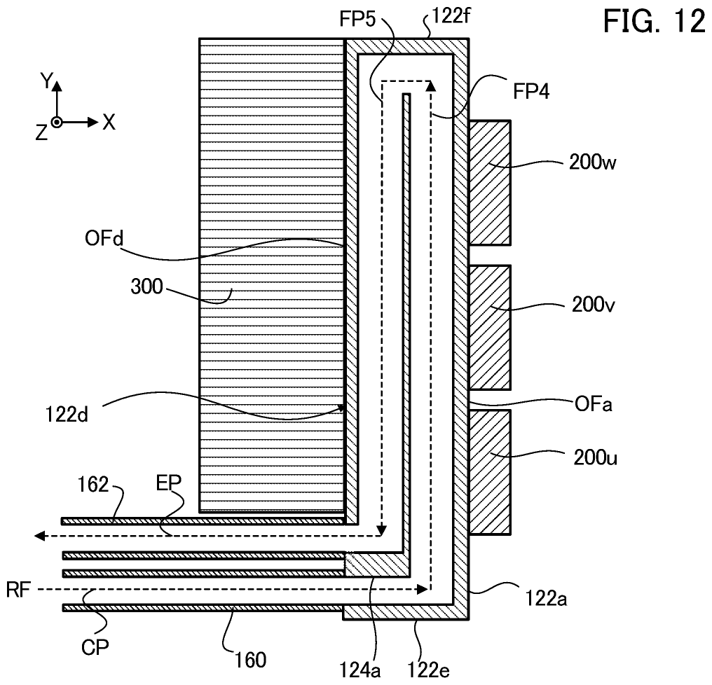

A flow path for a refrigerant in the cooler 100B included in the power converter 10C according to the third embodiment will be described with reference to FIG. 12.

FIG. 12 is a diagram showing the flow path for a refrigerant in the cooler 100B included in the power converter 10C according to the third embodiment. Specifically, FIG. 12 is a cross section of the power converter 10C in an XY plane passing through a straight line E shown in FIG. 10.

The refrigerant RF for flowing through the cooler 100B is supplied to the body 120A of the cooler 100B through the supply path CP of the supply pipe 160. The refrigerant RF then flows in the first flow path FP4 of the body 120A in the +Y direction. While flowing in the +Y direction, the refrigerant RF cools the semiconductor module 200 via the outer surface OFa, which is an example of the first cooling surface. The refrigerant RF then returns at an end of the body 120A in the +Y direction to flow in the second flow path FP5 of the body 120A in the −Y direction. While flowing in the −Y direction, the refrigerant RF cools the capacitor 300 via the outer surface OFd, which is an example of the second cooling surface. Finally, the refrigerant RF is drained from the body 120A of the cooler 100B through the drain path EP of the drain pipe 162.

### 3-2. Effects of Third Embodiment

In the power converter 10C, which is an example of the semiconductor device according to this embodiment, the cooler 100B includes the first flow path FP4 extending in the longitudinal direction of the cooler 100B, and the second flow path FP5 extending in the longitudinal direction of the cooler 100B. The first flow path FP4 is closer to the semiconductor module 200 than the second flow path FP5. In addition, the refrigerant RF, which has passed through the first flow path FP4, passes through the second flow path FP5.

The amount of heat generated by the semiconductor module 200 is usually greater than the amount of heat generated by the capacitor 300. Thus, it is necessary to preferentially cool the semiconductor module 200. The first flow path FP4, through which a lower temperature refrigerant RF flows, is closer to the semiconductor module 200 than the second flow path FP5, through which a higher temperature refrigerant RF flows. Therefore, the semiconductor module 200 can be preferentially cooled.

### 4. Fourth Embodiment

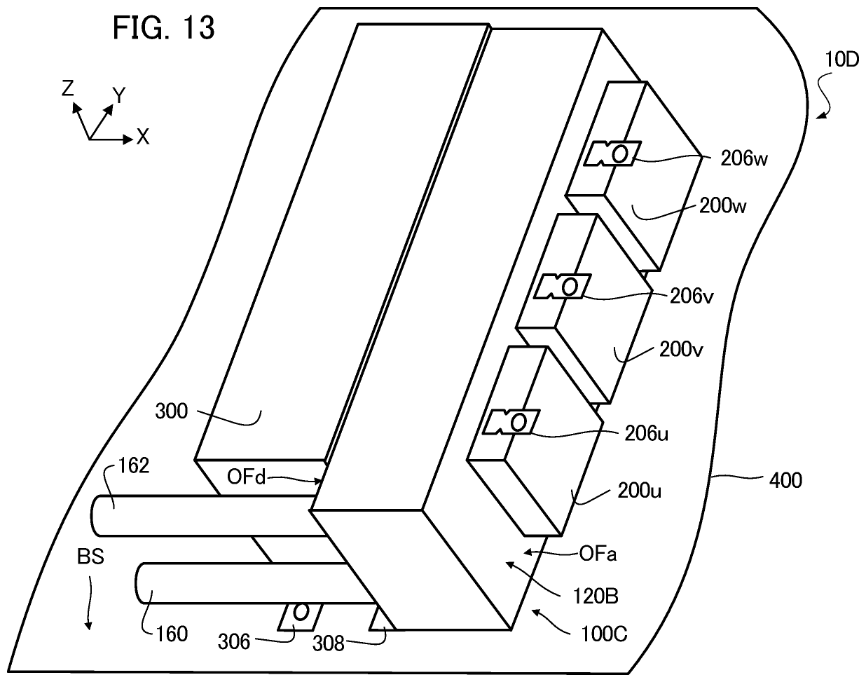

An example of an outline of a power converter 10D according to the fourth embodiment will be described with reference to FIG. 13. In the following description, to facilitate explanation, among elements of the power converter 10D according to the fourth embodiment, elements substantially the same as the elements of the power converter 10 according to the first embodiment are denoted with like reference signs, and detailed explanations thereof may be omitted. The following will mainly explain differences between the power converter 10D according to the fourth embodiment and the power converter 10 according to the first embodiment.

### 4-1. Configuration of Fourth Embodiment

FIG. 13 is a perspective view schematically showing a main part of the power converter 10D according to the fourth embodiment. The power converter 10D, which is different from the power converter 10 according to the first embodiment, includes a cooler 100C instead of the cooler 100. In the power converter 10 according to the first embodiment, the supply pipe 160 is coupled to one end portion of the outer surface OFd included in the cooler 100 in the −Y direction among the two end portions of the outer surface OFd, which are not in contact with the capacitor 300. In addition, the drain pipe 162 is coupled to the other end of the outer surface OFd in the +Y direction among the two end portions. In contrast, in the power converter 10D according to the fourth embodiment, both the supply pipe 160 and the drain pipe 162 are coupled to an end portion of the outer surface OFd in the −Y direction. Alternatively, both the supply pipe 160 and the drain pipe 162 may be coupled to the end portion of the outer surface OFd included in the cooler 100C in the +Y direction instead of the end portion of the outer surface OFd in the −Y direction. Although not shown in FIG. 13, the cooler 100C, which is different from the cooler 100 according to the first embodiment, includes a first flow path FP6 extending in a longitudinal direction of the cooler 100C, a second flow path FP7 extending in the longitudinal direction of the cooler 100C, and a plurality of third flow paths FP8 causing the first flow path FP6 and the second flow path FP7 to communicate with each other, as described below. The supply pipe 160 communicates with the first flow path FP6. On the other hand, the drain pipe 162 communicates with the second flow path FP7.

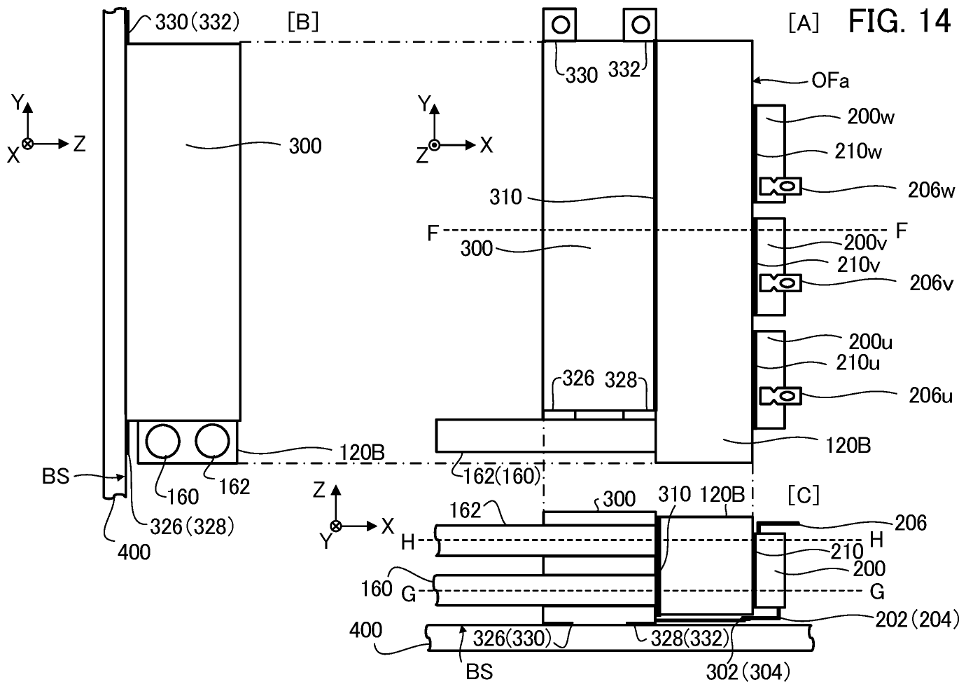

Details of a configuration of the power converter 10D according to the fourth embodiment will be described with reference to FIG. 14.

FIG. 14 is a diagram showing the configuration of the power converter 10D according to the fourth embodiment. FIG. 14 includes a diagram A, which is a plan view of the power converter 10D shown in FIG. 13 viewed in the −Z direction, a diagram B, which is a side view of the power converter 10D viewed in the +X direction, and a diagram C, which is a side view of the power converter 10D viewed in the +Y direction.

As shown in FIG. 14, the supply pipe 160 is spaced apart from the drain pipe 162 in the −Z direction. However, this is just an example. The supply pipe 160 may be spaced apart from the drain pipe 162 in the +Z direction. The supply pipe 160 and the drain pipe 162 may be spaced apart from each other by a freely selected distance as long as the supply pipe 160 and the drain pipe 162 are positioned on an end portion of the outer surface OFd in the −Y direction.

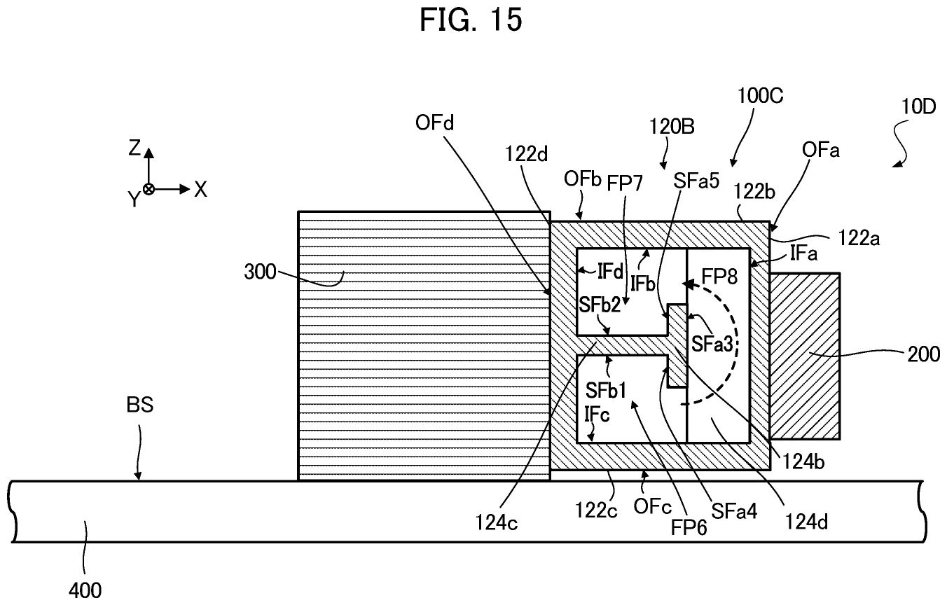

An internal structure of the cooler 100C included in the power converter 10D according to the fourth embodiment will be described with reference to FIG. 15.

FIG. 15 is a diagram showing the internal structure of the cooler 100C included in the power converter 10D according to the fourth embodiment. Specifically, FIG. 15 is a cross section of the power converter 10D in an XZ plane passing through a straight line F shown in FIG. 14.

A body 120B included in the cooler 100C, as well as the body 120 included in the cooler 100 according to the first embodiment, includes the outer walls 122a, 122b, 122c, and 122d.

In addition to the outer walls 122a, 122b, 122c, and 122d, the body 120B includes a plurality of partitions 124d arrayed in the Y direction. Each of the plurality of partitions 124d extends in the Z direction. As described below, two adjacent third flow paths FP8 among the plurality of third flow paths FP8 are separated from each other by a partition 124d arranged between the two adjacent third flow paths FP8. In other words, the plurality of third flow paths FP8 is arrayed in a longitudinal direction of the cooler 100C, and each of the plurality of third flow paths FP8 extends in a direction perpendicular to the longitudinal direction.

The body 120B includes partitions 124b and 124c. The partition 124b is arranged between the outer walls 122a and 122d. In other words, the partition 124b is spaced apart from the outer wall 122a in the −X direction. In this embodiment, it is assumed that the partition 124b is substantially parallel to the outer wall 122a. For example, a surface SFa3 of the partition 124b, which is a surface facing the inner surface IFa of the outer wall 122a, is substantially parallel to the inner surface IFa of the outer wall 122a. The surface SFa3 of the partition 124b may not be parallel to the inner surface IFa of the outer wall 122a. For example, the surface SFa3 of the partition 124b may be tilted such that an edge of the surface SFa3 in the +Z direction is farther from the outer wall 122a than any other portion of the surface SFa3.

The partition 124b between the outer walls 122a and 122d separates the first flow path FP6 and the plurality of third flow paths FP8 from each other. The partition 124b separates the second flow path FP7 and the plurality of third flow paths FP8 from each other. A space is provided between an edge of the partition 124b in the −Z direction and the inner surface IFc of the outer wall 122c. The space causes the first flow path FP6 and the plurality of third flow paths FP8 to communicate with each other. Similarly, a space, which causes the second flow path FP7 and the plurality of third flow paths FP8 to communicate with each other, is provided between an edge of the partition 124b in the +Z direction and the inner surface IFb of the outer wall 122b. In other words, in this embodiment, one end of each of the plurality of third flow paths FP8 communicates with the first flow path FP6, whereas the other end of each of the plurality of third flow paths FP8 communicates with the second flow path FP7.

The partition 124c is arranged between the outer walls 122b and 122c. The partition 124c is connected to the partition 124b and the outer wall 122d. For example, a surface SFb1 of the partition 124c, which is a surface facing the inner surface IFc of the outer wall 122c, is substantially parallel to the inner surface IFc of the outer wall 122c. A surface SFb2 of the partition 124c, which is a surface facing the inner surface IFb of the outer wall 122b, is substantially parallel to the inner surface IFb of the outer wall 122b.

The partition 124c between the outer walls 122b and 122c separates the first flow path FP6 and the second flow path FP7 from each other. A surface SFa4 of the partition 124b, the surface SFb1 of the partition 124c, the inner surface IFd of the outer wall 122d, and the inner surface IFc of the outer wall 122c each constitute a part of a wall surface of the first flow path FP6. A surface SFa5 of the partition 124b, the surface SFb2 of the partition 124c, the inner surface IFd of the outer wall 122d, and the inner surface IFb of the outer wall 122b each constitute a part of a wall surface of the second flow path FP7. The surface SFa4 of the partition 124b is a portion of a surface opposing the surface SFa3. The surface SFa4 of the partition 124b is positioned in the −Z direction from the partition 124c. The surface SFa5 of the partition 124b is a portion of the surface opposing the surface SFa3. The surface SFa5 of the partition 124b is positioned in the +Z direction from the partition 124c.

The partition 124d is a wall substantially perpendicular to the outer wall 122a. The partition 124d extends in the Z direction. For example, the partition 124d is arranged between the partition 124b and the outer wall 122a. The partition 124d is connected to the outer walls 122a, 122b, and 122c in addition to the partition 124b. In other words, in this embodiment, the partition 124d is connected to both the partition 124b and the outer wall 122a. The partition 124d may be connected to only one of the partition 124b and the outer wall 122a. Each of the plurality of third flow paths FP8 is arranged, for example, between two adjacent partitions 124d among the plurality of partitions 124d. The inner surface IFa of the outer wall 122a and the surface SFa3 of the partition 124b each constitute a part of a wall surface of each of the plurality of third flow paths FP8.

In other words, the plurality of third flow paths FP8 is closer to the semiconductor module 200 than the first flow path FP6 and the second flow path FP7 are.

In this embodiment, the outer wall 122a includes the inner surface IFa that constitutes a part of the wall surface of each of the plurality of third flow paths FP8. The semiconductor module 200 is mounted on the outer surface OFa of the outer wall 122a. Thus, for example, heat generated in the semiconductor module 200 is conducted from a surface of the semiconductor module 200, which faces the outer surface OFa of the outer wall 122a, to the refrigerant RF in the plurality of third flow paths FP8. The semiconductor module 200 is cooled by so-called one-side cooling. In addition, the refrigerant RF, which has cooled the semiconductor module 200, flows toward the capacitor 300 without stagnating. Therefore, the capacitor 300 can be efficiently cooled.

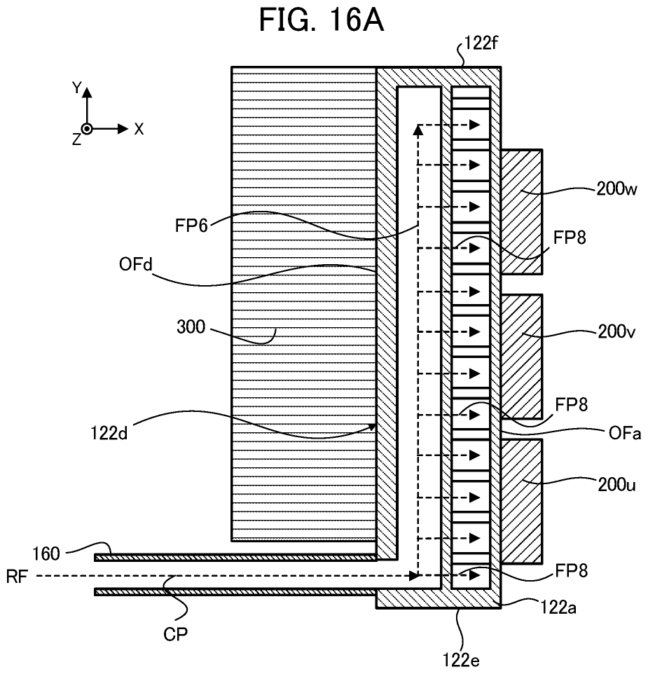

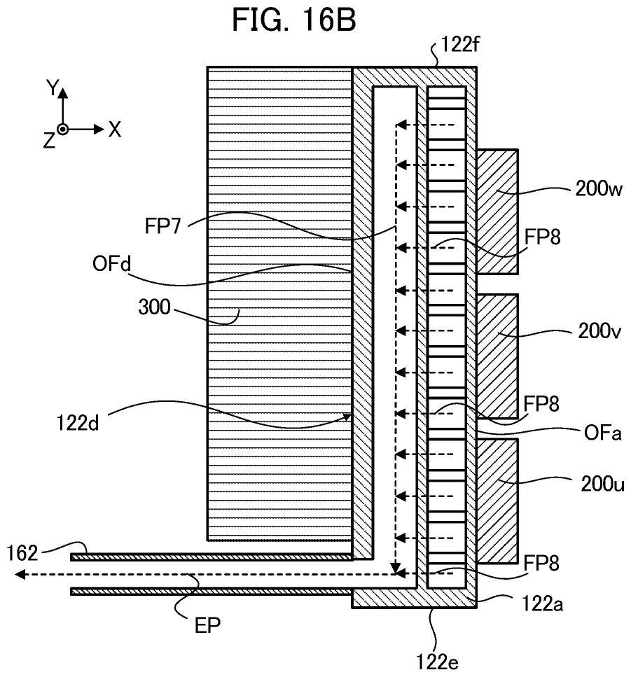

A flow path for a refrigerant in the cooler 100C included in the power converter 10D according to the fourth embodiment will be described with reference to FIG. 16A and FIG. 16B.

FIG. 16A and FIG. 16B are diagrams showing flow paths for a refrigerant in the cooler 100C included in the power converter 10D according to the fourth embodiment. Specifically, FIG. 16A is a cross section of the power converter 10D in an XY plane passing through a straight line G shown in FIG. 14. FIG. 16B is a cross section of the power converter 10D in an XY plane passing through a straight line H shown in FIG. 14.

The refrigerant RF for flowing through the cooler 100C is supplied to the body 120B of the cooler 100C through the supply path CP of the supply pipe 160. The refrigerant RF then flows in the first flow path FP6 of the body 120B in the +Y direction. While flowing in the +Y direction, the refrigerant RF cools the capacitor 300 via the outer surface OFd, which is an example of the second cooling surface. The refrigerant RF then flows in the third flow path FP8 of the body 120B in the +X direction, and then the refrigerant RF returns at the inner surface IFa of the outer wall 122a to flow in the −X direction. While flowing in the third flow path FP8, the refrigerant RF cools the semiconductor module 200 via the outer surface OFa that is an example of the first cooling surface. The refrigerant RF then flows in the second flow path FP7 of the body 120A in the −Y direction. While flowing in the −Y direction, the refrigerant RF cools the capacitor 300 via the outer surface OFd, which is an example of the second cooling surface. Finally, the refrigerant RF is drained from the body 120B of the cooler 100C through the drain path EP of the drain pipe 162.

### 4-2. Effects of Fourth Embodiment

In the power converter 10D, which is an example of the semiconductor device according to this embodiment, the cooler 100C includes the first flow path FP6 extending in the longitudinal direction of the cooler 100C, the second flow path FP7 extending in the longitudinal direction of the cooler 100C, and the plurality of third flow paths FP8 causing the first flow path FP6 and the second flow path FP7 to communicate with each other. The plurality of third flow paths FP8 is arrayed in the longitudinal direction of the cooler 100C, and each of the plurality of third flow paths FP8 extends in a direction perpendicular to the longitudinal direction. The plurality of third flow paths FP8 is closer to the semiconductor module 200 than the first flow path FP6 and the second flow path FP7 are.

According to the configuration described above, the refrigerant RF, which has cooled the semiconductor module 200, flows toward the capacitor 300 without stagnating. Therefore, the capacitor 300 can be efficiently cooled.

### 5: Modifications

This disclosure is not limited to the embodiments described above. Specific modifications will be described below. Two or more modifications freely selected from the following modifications may be combined as long as no conflict arises from such combination.

### 5-1. Modification 1

In the power converter 10D according to the fourth embodiment, the plurality of third flow paths FP8, which causes the first flow path FP6 and the second flow path FP7 to communicate with each other, is closer to the semiconductor module 200 than the first flow path FP6 and the second flow path FP7 are. However, the first flow path FP6 may be closer to the semiconductor module 200 than the second flow path FP7, and the plurality of third flow paths FP8 may be spaced apart from the first flow path FP6 and the second flow path FP7 in the +Z direction.

According to the configuration described above, fresh refrigerant RF can preferentially cool the semiconductor module 200.

### 5-2. Modification 2

In the power converter 10 according to the first embodiment, the capacitor 300 is electrically connected to the semiconductor module 200. However, an element electrically connected to the capacitor 300 is not limited to the semiconductor module 200. For example, the capacitor 300 may be electrically connected to a control substrate, which is not shown. Similarly, in the power converter 10B according to the second embodiment to the power converter 10D according to the fourth embodiment, an element electrically connected to the capacitor 300 is not limited to the semiconductor module 200.

### 5-3. Modification 3

In the power converter 10 according to the first embodiment, the cooler 100 cooled the capacitor 300. However, a target to be cooled by the cooler 100 is not limited to the capacitor 300. For example, the cooler 100 may cool a reactor instead of the capacitor 300. The target to be cooled by the cooler 100 is referred to as a “passive element.” The capacitor 300 and the reactor are each an example of “passive elements.” Similarly, in the power converter 10B according to the second embodiment to the power converter 10D according to the fourth embodiment, a target to be cooled is not limited to the capacitor 300.

### 5-4. Modification 4

In the power converter 10 according to the first embodiment, the cooler 100 and the semiconductor module 200 are coupled to each other via the TIM 210. Similarly, in the power converter 10, the cooler 100 and the capacitor 300 are coupled to each other via the TIM 310. However, the cooler 100 and the semiconductor module 200 may be in contact with each other not via a TIM. The cooler 100 and the capacitor 300 may be in contact with each other not via a TIM. Similarly, in the power converter 10B according to the second embodiment to the power converter 10D according to the fourth embodiment, the TIM may be omitted.

### 5-5. Modification 5

In the power converter 10 according to the first embodiment, thicknesses of the outer walls 122a to 122f are equal to each other. However, the thicknesses of the outer walls 122a to 122f may differ from each other. For example, the outer wall 122a may be thinner than the outer wall 122d. The amount of heat generated by the semiconductor module 200 is usually greater than the amount of heat generated by the capacitor 300. Thus, it is necessary to preferentially cool the semiconductor module 200. In a configuration in which the outer wall 122a adjacent to the semiconductor module 200 is thinner than the outer wall 122d adjacent to the capacitor 300, the semiconductor module 200 can be preferentially cooled. Similarly, in the power converter 10B according to the second embodiment to the power converter 10D according to the fourth embodiment, the thicknesses of the outer walls 122a to 122f may differ from each other.

### 5-6. Modification 6

In the power converter 10 according to the first embodiment, the body 120 is a hollow structure defined by the six outer walls 122a to 122f. However, the body 120 is not limited thereto. For example, the body 120 may be a multi-hole tube having a plurality of cooling flow paths. Similarly, in the power converter 10B according to the second embodiment to the power converter 10D according to the fourth embodiment, the body 120 is not limited to the hollow structure. In the power converter 10B according to the second embodiment, the first head 130 and the second head 132 may be each a multi-hole tube having a plurality of cooling flow paths.

### 5-7. Modification 7

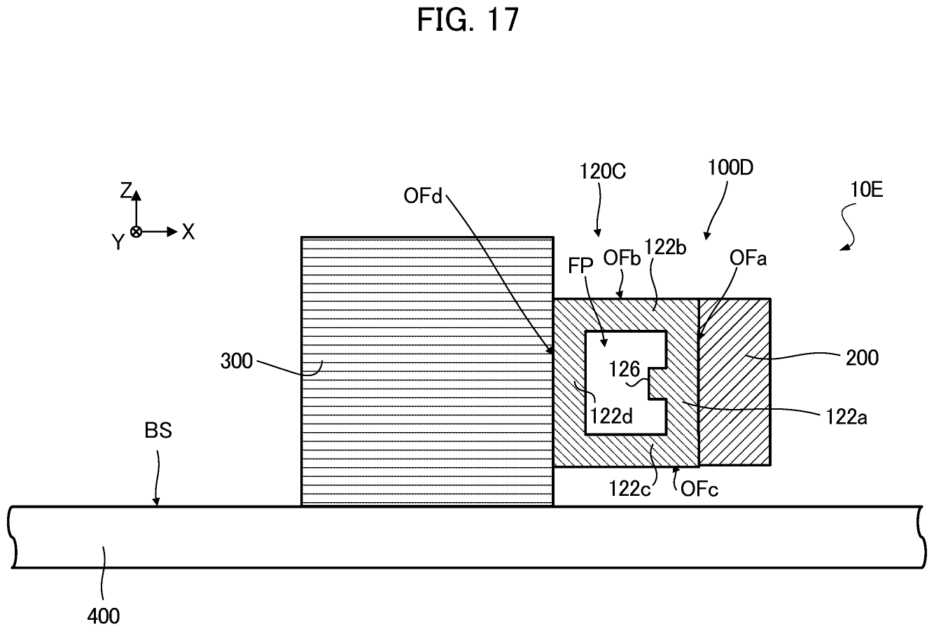

In the power converter 10 according to the first embodiment, at least one of the four outer walls 122a, 122b, 122c, and 122d may include a protrusion extending, for example, in the Y direction. FIG. 17 is a diagram showing an internal structure of a cooler 100D included in a power converter 10E according to this modification. Specifically, the power converter 10E is a modification of the power converter 10 according to the first embodiment. As shown in FIG. 17, in this modification, a protrusion 126 extending in the Y direction is mounted on the inner surface IFa included in the outer wall 122a. As a result, the refrigerant can readily flow through the entire cooler 100 to efficiently cool the entire semiconductor module 200 and the entire capacitor 300. Similarly, in the power converter 10B according to the second embodiment to the power converter 10D according to the fourth embodiment, at least one of the four outer walls 122a, 122b, 122c, and 122d may include a protrusion extending, for example, in the Y direction.

The embodiments and the modifications described above each include a semiconductor device including: a semiconductor module including one or more semiconductor elements; a cooler configured to cool the semiconductor module; a passive element electrically connected to the semiconductor module; and a housing containing the semiconductor module, the cooler and the passive element. The cooler includes: a first cooling surface on which the semiconductor module is mounted; a second cooling surface on which the passive element is mounted; and a fixed surface facing an interior wall of the housing. Such a configuration allows provision of a smaller semiconductor device.

The first cooling surface may be a surface facing the second cooling surface. The fixed surface may be a surface adjacent to the first cooling surface. The cooler may include a refrigerant pipe into which a refrigerant flows or from which the refrigerant is drained. The passive element may include a first surface cooled by the second cooling surface, and a second surface adjacent to the first surface. The second surface may be coupled to, or be in contact with, the refrigerant pipe. Such a configuration allows provision of a smaller semiconductor device. In addition, it is possible to cool the passive element.

### DESCRIPTION OF REFERENCE SIGNS

10, 10A, 10B, 10C, 10D . . . power converter, 100, 100A, 100B, 100C . . . cooler, 120, 120A, 120B . . . body, 122, 122a, 122b, 122c, 122d, 122e, 122f . . . outer wall, 124a, 124b, 124c, 124d . . . partition, 126 . . . protrusion, 130 . . . first head, 132 . . . second head, 150 . . . head, 160 . . . supply pipe, 162 . . . drain pipe, 200, 200u, 200v, 200w . . . semiconductor module, 202, 202u, 202v, 202w . . . input terminal, 204, 204u . . . input terminal, 206u, 206v, 206w . . . output terminal, 300 . . . capacitor, 302, 304 . . . output terminal, 400 . . . housing, 502, 504 . . . mounting portion, FP1 . . . first flow path, FP2 . . . second flow path, FP3 . . . third flow path, FP4 . . . first flow path, FP5 . . . second flow path, FP6 . . . first flow path, FP7 . . . second flow path, FP8 . . . third flow path.

What is claimed is:

1. A semiconductor device comprising:
an elongated cooler through which a refrigerant flows;
a plurality of semiconductor modules, each including one or more semiconductor elements; and
a passive element configured to drive the plurality of semiconductor modules,
wherein:
the cooler includes:
a first cooling surface; and
a second cooling surface opposing the first cooling surface,
the plurality of semiconductor modules is arrayed in a longitudinal direction of the cooler and is coupled to, or is in contact with, the first cooling surface, and
the passive element is coupled to, or is in contact with, the second cooling surface.

2. The semiconductor device according to claim 1, further comprising:
a housing containing the passive element, the cooler, and the plurality of semiconductor modules,
wherein:
the housing includes a mounting surface on which the passive element is mounted, and
a stacking direction of stacking of the passive element, the cooler, and the semiconductor module is parallel to the mounting surface.

3. The semiconductor device according to claim 2, wherein:
a space is provided not only between the plurality of semiconductor modules and the mounting surface, but also between the cooler and the mounting surface, and
a conductor is positioned in the space, the conductor electrically connecting the plurality of semiconductor modules and the passive element to each other.

4. The semiconductor device according to claim 2, wherein:
the passive element includes:
a first element surface coupled to, or in contact with, the second cooling surface; and
a second element surface that is one end surface of the passive element in the longitudinal direction of the cooler, the cooler includes:
a body including the first cooling surface and the second cooling surface; and
a first head being in contact with a first end portion of the body, the first head including a flow path communicating with a flow path inside the body,
the first head includes a third cooling surface that is a plane facing the second element surface, and
the third cooling surface is coupled to, or is in contact with, the second element surface.

5. The semiconductor device according to claim 4, wherein:
the passive element further includes a third element surface opposing the second element surface,
the cooler further includes a second head being in contact with a second end portion of the body, the second end portion of the body opposing the first end portion of the body, the second head including a flow path communicating with the flow path inside the body,
the second head includes a fourth cooling surface that is a plane facing the third element surface, and
the fourth cooling surface is coupled to, or is in contact with, the third element surface.

6. The semiconductor device according to claim 1, wherein:
the cooler includes:
a first wall including the first cooling surface;
a second wall including the second cooling surface; and
a flow path through which the refrigerant flows, the flow path being positioned between the first wall and the second wall, and the first wall is thinner than the second wall.

7. The semiconductor device according to claim 1, wherein
the cooler includes:
a first wall including the first cooling surface;
a second wall including the second cooling surface;
a flow path through which the refrigerant flows, the flow path being positioned between the first wall and the second wall; and
a protrusion protruding from an inner wall surface of the first wall, the inner wall surface of the first wall opposing the first cooling surface.

8. The semiconductor device according to claim 1, wherein:
the cooler includes:
a first flow path extending in the longitudinal direction of the cooler; and
a second flow path extending in the longitudinal of the cooler,
the first flow path is closer to the plurality of semiconductor modules than the second flow path, and
the refrigerant passes through the first flow path to pass through the second flow path.

9. The semiconductor device according to claim 1, wherein:
the cooler includes:
a first flow path extending in the longitudinal direction of the cooler;
a second flow path extending in the longitudinal direction of the cooler; and
a plurality of third flow paths causes the first flow path and the second flow path to communicate with each other,
the plurality of third flow paths is arrayed in the longitudinal direction, each of the plurality of third flow paths extending in a direction perpendicular to the longitudinal direction, and
the plurality of third flow paths is closer to the plurality of semiconductor modules than the first flow path and the second flow path are.

10. A semiconductor device comprising:
a semiconductor module including one or more semiconductor elements;
a cooler configured to cool the semiconductor module;
a passive element electrically connected to the semiconductor module; and
a housing containing the semiconductor module, the cooler, and the passive element,
wherein:
the cooler includes:
a first cooling surface on which the semiconductor module is mounted;
a second cooling surface on which the passive element is mounted; and
a fixed surface facing an interior wall of the housing, the fixed surface being fixed on the interior wall of the housing.

11. The semiconductor device according to claim 10, wherein the first cooling surface is a surface opposing the second cooling surface.

12. The semiconductor device according to claim 10, wherein the fixed surface is a surface adjacent to the first cooling surface.

13. The semiconductor device according to claim 10, wherein:
the cooler includes a refrigerant pipe into which a refrigerant flows or from which the refrigerant is drained, and
the passive element includes:
a surface cooled by the second cooling surface; and
a surface adjacent to the surface cooled by the second cooling surface, the surface adjacent to the surface cooled by the second cooling surface being coupled to, or being in contact with, the refrigerant pipe.
